(19) United States
(12) Patent Application Publication
(10) Pub. No.: US 2019/0148540 A1
(43) Pub. Date: May 16, 2019

(54) FLOATING GATE NON-VOLATILE MEMORY DEVICE

(71) Applicant: CHANG GUNG UNIVERSITY, TAOYUAN CITY (TW)

(72) Inventors: Jer-Chyi Wang, Taoyuan City (TW); Yu-Hua Liu, Taoyuan City (TW)

(73) Assignee: CHANG GUNG UNIVERSITY, TAOYUAN CITY (TW)

(21) Appl. No.: 16/189,369

(22) Filed: Nov. 13, 2018

(30) Foreign Application Priority Data
Nov. 14, 2017 (TW) 106139282

(51) Int. Cl. H01L 29/788; H01L 29/51; H01L 27/11517

(52) U.S. Cl. CPC H01L 29/788; H01L 27/11517; H01L 29/516

(57) ABSTRACT

A floating gate non-volatile memory device includes at least one floating gate non-volatile memory cell including a semiconductor substrate, a gate stack unit, and a drain and source unit. The gate stack unit includes a tunnel oxide layer having a negative capacitance, a floating gate layer disposed on the tunnel oxide layer, a blocking oxide layer disposed on the floating gate layer and opposite to the tunnel oxide layer, and a control gate layer disposed on the blocking oxide layer and opposite to the floating gate layer. The drain and source unit is disposed in the semiconductor substrate and includes source and drain regions that are respectively disposed on two opposite sides of the gate stack unit.

### CROSS-REFERENCE TO RELATED APPLICATION

This application claims priority to Taiwanese Invention Patent Application No. 106139282, filed on Nov. 14, 2017.

### FIELD

The disclosure relates to a floating gate non-volatile memory device, and more particularly to a floating gate non-volatile memory device including a tunnel oxide layer having a negative capacitance.

### BACKGROUND

Unlike in a volatile memory, data stored in a non-volatile memory is still retained even if an electric energy is not applied to the non-volatile memory, and thus the non-volatile memory has been widely used in portable electronic devices. Moreover, the non-volatile memory has advantages of small volume, light weight, and saving energy. With the trend of miniaturization of the electronic device, it is desirable in the art to maintain the performance of the non-volatile memory while reducing the size thereof.

Generally, a non-volatile flash memory is based on a floating gate transistor structure. The non-volatile flash memory based on the floating gate transistor is hereinafter referred to as a floating gate non-volatile memory. When the floating gate non-volatile memory is miniaturized, a thickness of a tunnel oxide layer included therein will be reduced for increasing charge injection efficiency of the memory so as to enhance memory efficiency. However, since the tunnel oxide layer of the floating gate non-volatile memory is generally made from silicon oxide, a leakage current tends to occur when the tunnel oxide layer is thinned down, which results in an undesired data loss from the conventional floating gate non-volatile memory. If the problem of the leakage current is to be avoided, the thickness of the tunnel oxide layer needs to be increased, which unavoidably decreases the charge injection efficiency, and results in the performance of the conventional floating gate non-volatile memory being hardly enhanced.

Therefore, there is plenty of room for improving the charge injection efficiency of the LED device without worsening the problem of the leakage current.

### SUMMARY

Therefore, an object of the disclosure is to provide a floating gate non-volatile memory device that can alleviate at least one of the drawbacks of the prior art.

According to the disclosure, a floating gate non-volatile memory device includes at least one floating gate non-volatile memory cell including a semiconductor substrate, a gate stack unit, and a drain and source unit.

The gate stack unit includes a tunnel oxide layer, a floating gate layer, a blocking oxide layer, and a control gate layer. The tunnel oxide layer has a negative capacitance and is disposed on the semiconductor substrate. The floating gate layer is disposed on the tunnel oxide layer. The blocking oxide layer is disposed on the floating gate layer and is opposite to the tunnel oxide layer. The control gate layer is disposed on the blocking oxide layer and is opposite to the floating gate layer.

The drain and source unit is disposed in the semiconductor substrate and includes source and drain regions that are respectively disposed on two opposite sides of the gate stack unit.

### BRIEF DESCRIPTION OF THE DRAWINGS

Other features and advantages of the disclosure will become apparent in the following detailed description of the embodiment with reference to the accompanying drawings, of which:

FIG. 1 is a schematic view illustrating an embodiment of a floating gate non-volatile memory device according to the disclosure, which includes a plurality of floating gate non-volatile memory cells;

FIG. 2 is a schematic view illustrating one of the floating gate non-volatile memory cells;

FIG. 3 is a perspective partly cutaway view illustrating a modification of a semiconductor substrate and a gate stack unit of one of the floating gate non-volatile memory cells; and

FIG. 4 is a plot of a drain-source current (I_{DS}) versus a working voltage (V_{G}) applied to a control gate layer of the floating gate non-volatile memory cell of FIG. 2 at different drain-source voltages (V_{DS}).

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

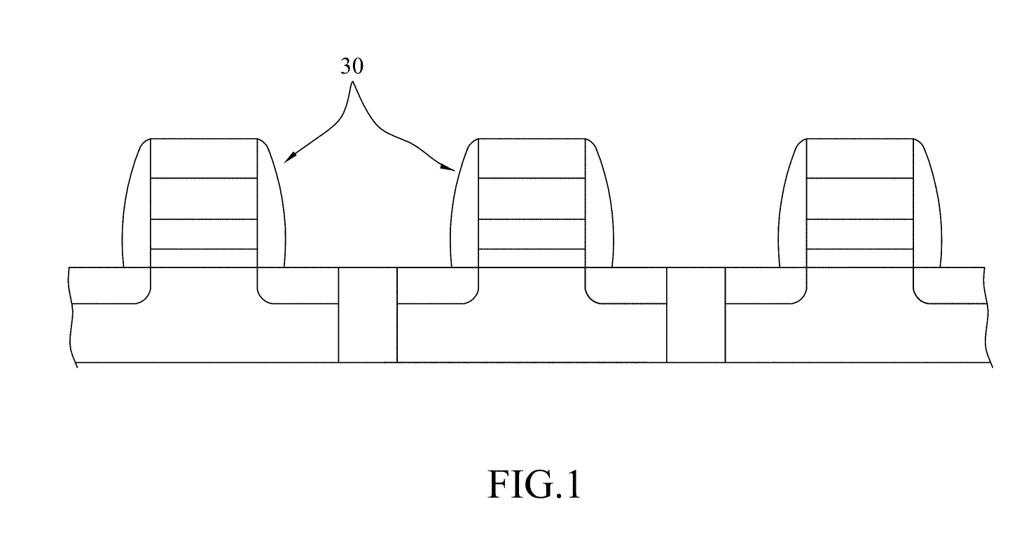

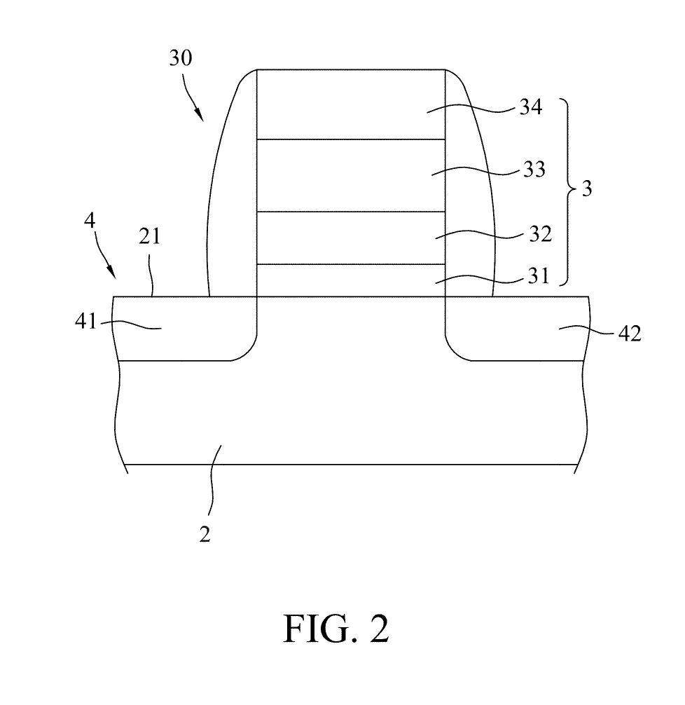

Referring to FIGS. 1 and 2, an embodiment of a floating gate non-volatile memory device according to the disclosure is illustrated. The floating gate non-volatile memory device may include at least one floating gate non-volatile memory cell 30. In this embodiment, the floating gate non-volatile memory device includes a plurality of the floating gate non-volatile memory cell 30 arranged in an array (only three are shown in FIG. 1 and only one is shown in FIG. 2). Each of the floating gate non-volatile memory cells 30 includes a semiconductor substrate 2, a gate stack unit 3, and a drain and source unit 4.

The semiconductor substrate 2 is made from one of indium tin oxide (ITO), indium gallium zinc oxide (IGZO), group IV A elements, III A-VA compound semiconductors, transition metal dichalcogenides (TMDs), and a two-dimensional (2D) semiconductor material, the 2D semiconductor material being a material which has a layered atomic structure, e.g., graphene. Specifically, the semiconductor substrate 2 is selected from a doped-semiconductor material. In this embodiment, the semiconductor substrate 2 is a p-type silicon substrate.

The gate stack unit 3 includes: a tunnel oxide layer 31 that has negative capacitance and that is disposed on the semiconductor substrate 2; a floating gate layer 32 that is disposed on the tunnel oxide layer 31; a blocking oxide layer 33 that is disposed on the floating gate layer 32 and that is opposite to the tunnel oxide layer 31; and a control gate layer 34 that is disposed on the blocking oxide layer 33 and that is opposite to the floating gate layer 32. In this embodiment, the tunnel oxide layer 31 is exemplified to be made from a ferroelectric material.

In this embodiment, the tunnel oxide layer 31 of the gate stack unit 3 is directly disposed on the semiconductor substrate 2, the floating gate layer 32 is directly disposed on the tunnel oxide layer 31, the blocking oxide layer 33 is directly disposed on the floating gate layer 32, and the control gate layer 34 is directly disposed on the blocking oxide layer 33.

The drain and source unit 4 is disposed in the semiconductor substrate 2 and includes source and drain regions 41, 42 that are respectively disposed on two opposite sides of the gate stack unit 3. In this embodiment, each of the source and drain regions 41, 42 extends inwardly of the semiconductor substrate 2 from a top surface 21 thereof.

In the following description, the one of the floating gate non-volatile memory cells 30 shown in FIG. 2 is used as an example to illustrate operation of the entire floating gate non-volatile memory device. When a sufficiently high electric voltage is applied to the control gate layer 34, charges in the semiconductor substrate 2 will be attracted so as to accumulate, be pulled from the semiconductor substrate 2 through the tunnel oxide layer 31 into the floating gate layer 32, and be stored in the floating gate layer 32. In this embodiment, the charges are exemplified by electrons. The blocking oxide layer 33, interposed between the floating gate layer 32 and the control gate layer 34, prevents the electrons from passing straight through the floating gate layer 32 and leaking out of the control gate layer 34.

With inclusion of the tunnel oxide layer 31 having the negative capacitance, a coupling ratio (CR) of the gate floating non-volatile memory cell 30 is enhanced, so that a charge injection efficiency of the gate floating non-volatile memory cell 30 is increased.

To be specific, the coupling ratio (CR) of the gate floating non-volatile memory cell 30 is a ratio of C_{BO} to C_{T}. The relationship of the CR, V_{fg} and V_{G} is presented by an equation (1) as follows:

$${V}_{fg} = \frac{{C}_{BO}}{{C}_{T}} {V}_{G} \qquad ( 1 )$$

C_{T} satisfies an equation (2) as follows:

C_{T}=C_{BO}+C_{FB}+C_{FS}+C_{FD}+C_{SB}+C_{DB}+C_{FF} (2)

When the equation (2) is substituted into the equation (1), the coupling ratio (CR) is a ratio of the C_{BO} to (C_{BO}+C_{FB}+C_{FS}+C_{FD}+C_{SB}+C_{DB}+C_{FF}). The relationship between the CR, the V_{fg} and the V_{G} is presented by an equation (3) as follows:

$${V}_{fg} = \frac{{C}_{BO}}{{C}_{BO} + {C}_{FB} + {C}_{FS} + {C}_{FD} + {C}_{SB} + {C}_{DB} + {C}_{FF}} {V}_{G} \qquad ( 3 )$$

In the above equations (1) to (3), the C_{T} is a total equivalent capacitance of the gate floating non-volatile memory cell 30; the C_{BO} is a capacitance between the control gate layer 34 and the floating gate layer 32 and is also known as a capacitance of the blocking oxide layer 33; the C_{FB} is a capacitance between the floating gate layer 32 and the semiconductor substrate 2; the C_{FS} is a capacitance between the floating gate layer 32 and the source region 41; the C_{FD} is a capacitance between the floating gate layer 32 and the drain region 42; the C_{SB} is a capacitance between the source region 41 and the semiconductor substrate 2; the C_{DB} is a capacitance between the drain region 42 and the semiconductor substrate 2; the C_{FF} is an equivalent capacitance of the floating gate layer 32; the V_{fg} is defined as a voltage drop from the control gate layer 34 to the floating gate layer 32; and the V_{G} is a working voltage applied to the control gate layer 34. With the miniaturization of the floating gate non-volatile memory device, a distance between any two adjacent ones of the semiconductor substrate 2, the source region 42, the drain region 41, the tunnel oxide layer 31, the floating gate layer 32, the blocking oxide layer 33 and the control gate layer 34 of the floating gate non-volatile memory cell 30 is decreased, and parasitic capacitance effects may be worsened. In the embodiment, the C_{FF}, the C_{FB}, the C_{FS}, the C_{FD}, the C_{SB} and the C_{DB} are the parasitic capacitances of the floating gate non-volatile memory cell 30.

Specifically, the coupling ratio (CR) presented in the equation (3) is a ratio of the C_{BO} to the C_{T}, in which the C_{T} is equal to the sum of the C_{BO}, the C_{FB}, the C_{FS}, the C_{FD}, the C_{SB}, the C_{DB}, and the C_{FF}. The V_{fg} is a product of the V_{G} multiplied by the CR. Under a predetermined value of the V_{G}, the V_{fg} will increase when the CR increases, and the ability of the floating gate non-volatile memory cell 30 to pull electrons from the semiconductor substrate 2 and to accumulate the pulled electrons in the floating gate layer 32 is enhanced, thus the charge injection efficiency of the floating gate non-volatile memory cell 30 is improved. Generally, for maintaining required reliability of the conventional floating gate non-volatile memory device, the miniaturization of the floating gate non-volatile memory device is limited and the blocking oxide layer 33 is required to have a certain thickness. The thickness requirement for the blocking oxide layer 33 causes the V_{fg} to be not increasable, and thus, the CR cannot be further enhanced.

According to the disclosure, inclusion of the tunnel oxide layer 31 having the negative capacitance results in a negative value of the C_{FB}, thus the total equivalent capacitance of the gate stack unit 3 (C_{T}) may be decreased, even to a negative value. Referring back to the equation (3), a decrease in the C_{FB} results in a decrease in the denominator of the ratio of C_{BO}/C_{T} of the CR, and thus the CR is increased and the charge injection efficiency of the floating gate non-volatile memory cell 30 is enhanced accordingly. Since the V_{G} can be decreased in view of the increased CR, compared with the conventional floating gate non-volatile memory device, the V_{fg} of the floating gate non-volatile memory cell 30 of the disclosure can be obtained from a relatively low V_{G}.

On the contrary, when the tunnel oxide layer 31 is made from the ferroelectric material but does not have the negative capacitance, the C_{FB} cannot be decreased and thus the CR will not increased. Hence, the charge injection efficiency of the floating gate non-volatile memory cell 30 cannot be enhanced. Therefore, for enhancing the charge injection efficiency of the floating gate non-volatile memory cell 30, the ferroelectric material used for making the tunnel oxide layer 31 is required to impart the negative capacitance to the resulting tunnel oxide layer 31.

In this embodiment, the tunnel oxide layer 31 of the gate stack unit 3 may be made by: sequentially forming a tunnel oxide preformed layer from the ferroelectric material and a floating gate layer 32 on the semiconductor substrate 2, and annealing the tunnel oxide preformed layer at a temperature that ranges from 500° C. to 700° C. The annealed ferroelectric material has a preferred crystalline phase and the negative capacitance to impart both the ferroelectricity and the negative capacitance to the tunnel oxide layer 31. Specifically, by way of imparting the negative capacitance to the tunnel oxide layer 31 with the ferroelectric material, the C_{FB} can be decreased without decreasing the thickness of the tunnel oxide layer 31, and thus the charge injection efficiency of the floating gate non-volatile memory cell 30 can be enhanced, and a problem of a leakage current caused by thinning the tunnel oxide layer 31 can be avoided. Specifically, the thickness of the tunnel oxide layer 31 ranges from 10 nm to 30 nm. When the thickness of the tunnel oxide layer 31 is less than 10 nm, the leakage current tends to occur. When the thickness of the tunnel oxide layer 31 is greater than 30 nm, the crystal phase of the ferroelectric material is poor and may fail to impart the ferroelectricity and the negative capacitance to the tunnel oxide layer 31. In this embodiment, the thickness of the tunnel oxide layer 31 is exemplified to be 20 nm.

The ferroelectric material used for making the tunnel oxide layer 31 may be an electrical insulating material having a relatively high dielectric coefficient (high-k), the ferroelectricity and the negative capacitance. Specifically, the ferroelectric material may be selected from an inorganic material such as hafnium oxide (HfO₂), ceramic materials such as barium titanate (BaTiO₃) and lead zirconate titanate (PZT), and an organic material such as poly(vinylidene fluoride-trifluoroethylene). Alternatively, the ferroelectric material for making the tunnel oxide layer 31 may be a doped HfO₂-based material that is doped with a dopant selected from the group consisting of silicon (Si), zirconium (Zr), gadolinium (Gd), aluminum (Al), yttrium (Y), strontium (Sr), lanthanum (La) and samarium (Sm). The floating gate layer 32 of the gate stack unit 3 may be made from one of gold (Au), platinum (Pt), silver (Ag), tungsten (W), ruthenium (Ru), copper (Cu), cobalt (Co), molybdenum (Mo), nickel (Ni), hafnium (Hf), aluminum (Al), cobalt silicide (CoSi₂), nickel silicide (NiSi₂), hafnium nitride (HfN), titanium nitride (TiN), tantalum nitride (TaN), graphene, and polycrystalline silicon. The blocking oxide layer 31 of the gate stack unit 3 may be made from one of silicon dioxide (SiO₂) and a high dielectric constant material.

In one form, the tunnel oxide layer 31 of negative capacitance is made from an anti-ferroelectric material that may be selected from a PbZr-based material, ZrO₂ and HfZrO. The PbZr-based material may include (Pb, Ba)ZrO₃, (Pb, Sr)ZrO₃, (Pb, La) (Zr, Ti)O₃, (Pb, La) (Zr, Sn, Ti)O₃ (PLZST) and (Pb, Nb) (Zr, Sn, Ti)O₃ (PNZST).

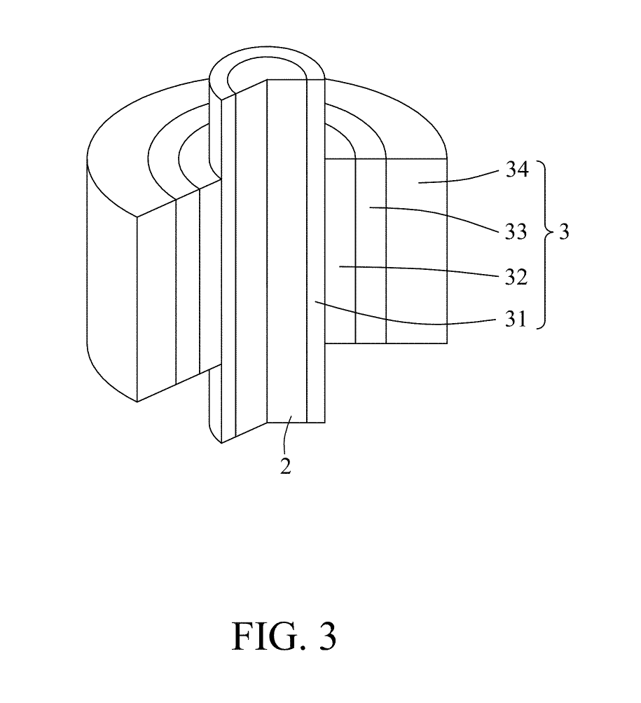

Referring to FIG. 3, a modification of the floating gate non-volatile memory cell of the floating gate non-volatile memory device is partly illustrated. The gate stack unit 3 surrounds the semiconductor substrate 2. The source and drain regions (not shown) may be respectively disposed in two opposite sides of the semiconductor substrate 2. The modification of the floating gate non-volatile memory cell is also known as a vertical field-effect transistor.

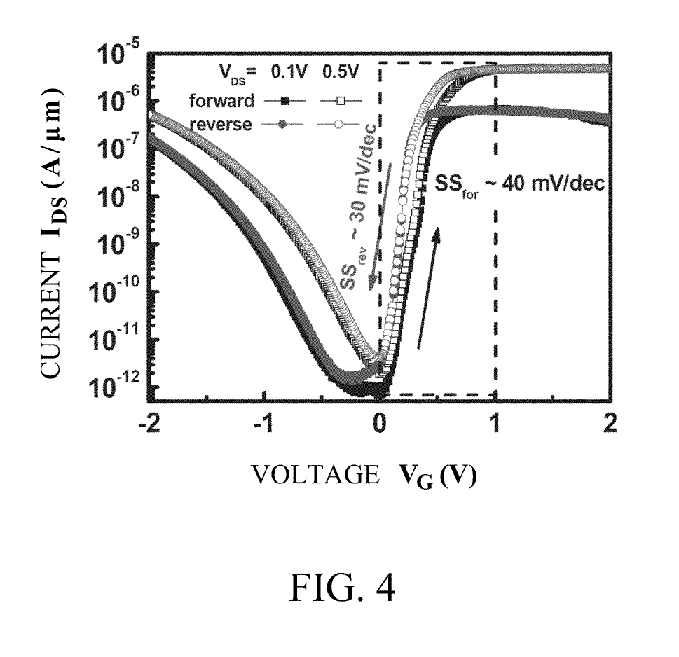

Referring to FIG. 4, curves of a drain-source current (I_{DS}) versus the working voltage applied to the control gate layer 34 (V_{G}) of the floating gate non-volatile memory cell 30 shown in FIG. 2 at different drain-source voltages (V_{DS}) are illustrated. To be specific, the curve obtained from data points marked with “▪” illustrates the I_{DS} measured at the V_{G} ranging from −2 V to +2 V and at a forward V_{DS} of 0.1 V. The curve obtained from data points marked with “□” illustrates the I_{DS} measured at the V_{G} ranging from −2 V to +2 V and at a forward V_{DS} of 0.5 V. The curve obtained from data points marked with “●” illustrates the I_{DS} measured at the V_{G} ranging from −2 V to +2 V and at an inverse V_{DS} of 0.1 V. The curve obtained from data points marked with “◯” illustrates the I_{DS} measured at the V_{G} ranging from −2 V to +2 V and at an inverse V_{DS} of 0.5 V. The results show that the floating gate non-volatile memory cell 30 of the floating gate non-volatile memory device of the disclosure has a subthreshold swing, ranging from 30 to 40 mV/decade, which is much lower than that of the conventional floating gate memory including the tunnel oxide layer 31 with a positive capacitance, which is 60 mV/decade. Hence, the switching capability of the floating gate non-volatile memory cell 30 is improved, and the V_{G} of the control gate layer 34 of the floating gate non-volatile memory cell 30 can be decreased.

To sum up, by virtue of the inclusion of the tunnel oxide layer 31 having the negative capacitance and made from the ferroelectric material, the C_{FB} can be decreased, even to be a negative value, without decreasing the thickness of the tunnel oxide layer 31, and thus the CR can be increased and the working voltage of the floating gate layer 32 can be decreased simultaneously. Hence, the charge injection efficiency of the floating gate non-volatile memory cells 30, i.e., of the entire floating gate non-volatile memory device, can be enhanced.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A floating gate non-volatile memory device, comprising:
at least one floating gate non-volatile memory cell including
a semiconductor substrate;
a gate stack unit including
a tunnel oxide layer having a negative capacitance and disposed on said semiconductor substrate,
a floating gate layer disposed on said tunnel oxide layer,
a blocking oxide layer disposed on said floating gate layer and opposite to said tunnel oxide layer, and
a control gate layer disposed on said blocking oxide layer and opposite to said floating gate layer; and
a drain and source unit disposed in said semiconductor substrate and including source and drain regions respectively disposed on two opposite sides of said gate stack unit.

2. The floating gate non-volatile memory device of claim 1, wherein said tunnel oxide layer is made from a ferroelectric material selected from the group consisting of hafnium oxide (HfO₂), barium titanate, lead zirconate titanate, and poly(vinylidene fluoride-trifluoroethylene).

3. The floating gate non-volatile memory device of claim 1, wherein said tunnel oxide layer is made from an anti-ferroelectric material selected from a PbZr-based material, ZrO₂ and HfZrO.

4. The floating gate non-volatile memory device of claim 3, wherein the PbZr-based material is selected from the group consisting of (Pb, Ba)ZrO₃, (Pb, Sr)ZrO₃, (Pb, La)(Zr, Ti)O₃, (Pb, La)(Zr, Sn, Ti)O₃ (PLZST), (Pb, Nb)(Zr, Sn, Ti)O₃ (PNZST) and combinations thereof.

5. The floating gate non-volatile memory device of claim 1, wherein said tunnel oxide layer of said gate stack unit is directly disposed on said semiconductor substrate, said floating gate layer being directly disposed on said tunnel oxide layer, said blocking oxide layer being directly disposed on said floating gate layer, said control gate layer being directly disposed on said blocking oxide layer.

6. The floating gate non-volatile memory device of claim 1, wherein said tunnel oxide layer is made from a ferroelectric material selected from a doped HfO₂-based material that is doped with a dopant selected from the group consisting of silicon, zirconium (Zr), gadolinium (Gd), aluminum (Al), yttrium (Y), strontium (Sr), lanthanum (La) and samarium (Sm).

7. The floating gate non-volatile memory device of claim 1, wherein said tunnel oxide layer of said gate stack unit has a thickness ranging from 10 nm to 30 nm.

8. The floating gate non-volatile memory device of claim 1, wherein said gate stack unit surrounds said semiconductor substrate.

9. The floating gate non-volatile memory device of claim 1, wherein said floating gate layer of said gate stack unit is made from one of gold (Au), platinum (Pt), silver (Ag), tungsten (W), ruthenium (Ru), copper (Cu), cobalt (Co), molybdenum (Mo), nickel (Ni), hafnium (Hf), aluminum (Al), cobalt silicide (CoSi₂), nickel silicide (NiSi₂), hafnium nitride (HfN), titanium nitride (TiN), tantalum nitride (TaN), graphene, and polycrystalline silicon.

10. The floating gate non-volatile memory device of claim 1, wherein said blocking oxide layer of said gate stack unit is made from one of silicon dioxide (SiO₂) and a high dielectric constant material.

11. The floating gate non-volatile memory device of claim 1, wherein said semiconductor substrate is made from one of indium tin oxide (ITO), indium gallium zinc oxide (IGZO), group IV A elements, III A-VA compound semiconductors, and two-dimensional semiconductor material.
